(19) United States
(12) Patent Application Publication
(10) Pub. No.: US 2022/0264749 A1
(43) Pub. Date: Aug. 18, 2022

(54) ELECTRONIC SUBSTRATE AND ELECTRONIC APPARATUS

(71) Applicant: LENOVO (SINGAPORE) PTE. LTD., SINGAPORE (SG)

(72) Inventors: Hirohide Komiyama, YOKOHAMA (JP); Seiji Yamasaki, YOKOHAMA (JP)

(73) Assignee: LENOVO (SINGAPORE) PTE. LTD., SINGAPORE (SG)

(21) Appl. No.: 17/457,116

(22) Filed: Dec. 1, 2021

(30) Foreign Application Priority Data
Feb. 17, 2021 (JP) 202123409

(51) Int. Cl. H05K 3/30; G06F 1/16

(52) U.S. Cl. CPC H05K 3/305; G06F 1/1633

(57) ABSTRACT

An electronic substrate includes: a body having a mounting surface; an electronic component having an opposed surface facing the mounting surface; and an adhesive layer that bonds the electronic component to the mounting surface. The mounting surface has a storage recess that stores at least a part of the adhesive layer. The storage recess is located from a first area overlapping the opposed surface to a second area not overlapping the opposed surface in plan view.

### FIELD OF THE INVENTION

The present invention relates to an electronic substrate and an electronic apparatus.

### BACKGROUND OF THE INVENTION

Electronic substrates for electronic apparatuses such as laptop personal computers (PCs) have electronic components such as CPUs mounted thereon. The electronic components are bonded to the mounting surface of the electronic substrate by an adhesive, for example (see, for example, Japanese Unexamined Patent Application Publication No. 2010-129902).

### SUMMARY OF THE INVENTION

In recent years, there have been demands for smaller and lighter electronic apparatuses, high-performance audio equipment, higher battery capacity, and more antennas. To meet these demands, it is required to reduce the size of the electronic substrate.

One aspect of the present invention aims to provide electronic substrates and electronic apparatuses that can be made compact.

According to one aspect of the present invention, an electronic substrate includes: a body having a mounting surface; an electronic component having an opposed surface facing the mounting surface; and an adhesive layer that bonds the electronic component to the mounting surface. The mounting surface has a storage recess that stores at least a part of the adhesive layer.

Preferably, the electronic substrate has a first area overlapping the opposed surface and a second area not overlapping the opposed surface in plan view, and the storage recess is located from the first area to the second area.

Preferably the electronic component is rectangular in plan view, and the storage recess involves at least one corner of the electronic component in plan view.

In the electronic substrate, the storage recess may have an inner side face having recesses and protrusions thereon.

The electronic component may include a processor, and the electronic substrate includes at least one bypass capacitor on the mounting surface at a position opposing the outer edge of the electronic component in plan view.

Another aspect of the present invention provides an electronic apparatus including the electronic substrate as described above.

One aspect of the present invention provides electronic substrates and electronic apparatuses that can be made compact.

### BRIEF DESCRIPTION OF THE DRAWINGS

FIG. 1 is a plan view of an electronic substrate according to one embodiment.

FIG. 2 is a partial plan view of the electronic substrate according to one embodiment.

FIG. 3 is a partial cross-sectional view of the electronic substrate according to one embodiment.

FIG. 4 is a cross-sectional view of a body of the electronic substrate according to one embodiment.

FIG. 5 is a plan view of the internal structure of a second chassis of the electronic apparatus according to one embodiment.

FIG. 6 is a perspective view of an electronic apparatus according to one embodiment.

FIG. 7 is a plan view of a storage recess that is a modified example.

### DETAILED DESCRIPTION OF THE INVENTION

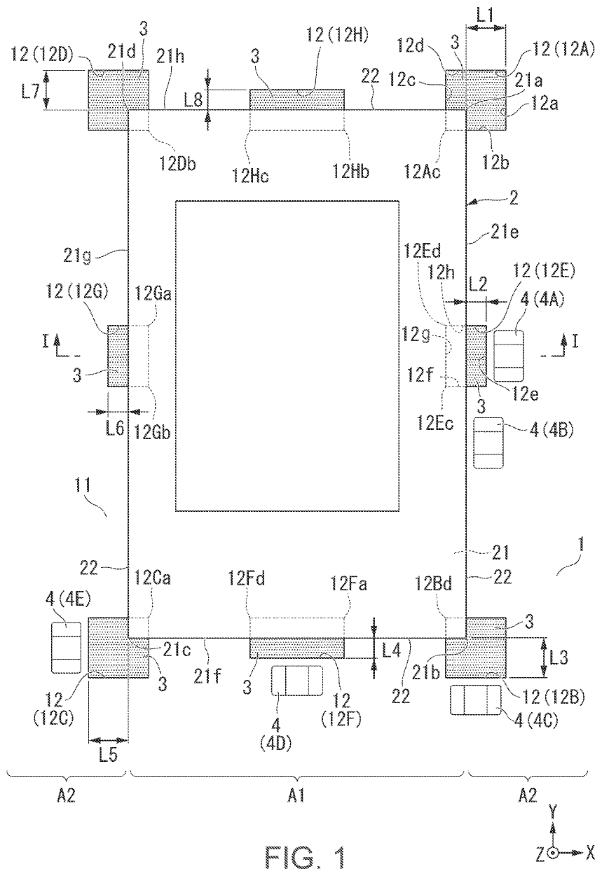

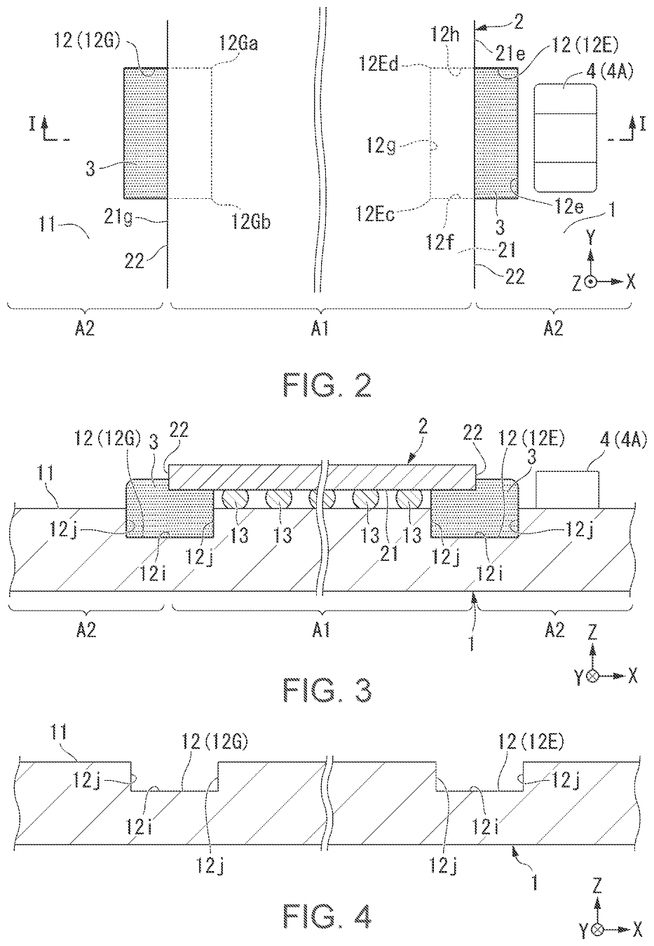

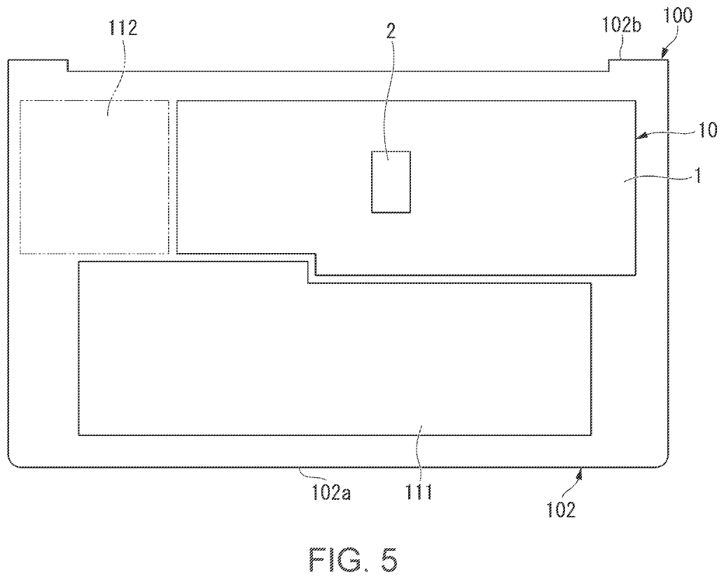

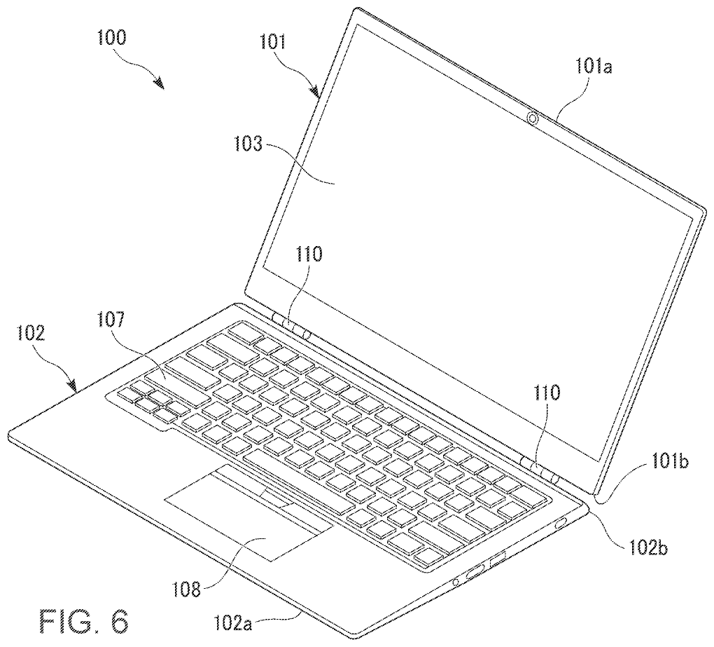

FIG. 1 is a plan view of an electronic substrate 10 according to one embodiment. FIG. 2 is a partial plan view of the electronic substrate 10. FIG. 3 is a partial cross-sectional view of the electronic substrate 10. FIG. 3 illustrates the view taken along the line I-I in FIGS. 1 and 2. FIG. 4 is a cross-sectional view of a body 1 of the electronic substrate 10. FIG. 5 is a plan view of the internal structure of a second chassis 102 of the electronic apparatus 100. FIG. 6 is a perspective view of the electronic apparatus 100.

[Electronic Apparatus]

As illustrated in FIG. 6, an electronic apparatus 100 includes a first chassis 101 and a second chassis 102. In one example, the electronic apparatus 100 is a laptop PC.

The first chassis 101 and the second chassis 102 are connected to each other at their ends via a hinge mechanism 110. The first chassis 101 is rotatable relative to the second chassis 102 around the rotary shaft of the hinge mechanism 110. The first chassis 101 has a first base end 101b provided with the hinge mechanism 110. The first chassis 101 has a first open end 101a on the opposite side of the first base end 101b. The second chassis 102 has a second base end 102b provided with the hinge mechanism 110. The second chassis 102 has a second open end 102a on the opposite side of the second base end 102b.

The second chassis 102 has a rectangular plate shape. The second chassis 102 has a keyboard 107 and a touchpad 108 placed thereon. These keyboard 107 and touchpad 108 are examples of the input device. The second chassis 102 is also called a system chassis.

The first chassis 101 holds a display 103. In one example, the display 103 is a liquid crystal display or an organic electro-luminescence (EL) display. The first chassis 101 is also called a display chassis.

As illustrated in FIG. 5, the second chassis 102 is provided with the electronic substrate 10, a battery 111, and a heat dissipation mechanism 112.

The battery 111 supplies power to the devices in the electronic apparatus 100. The heat dissipation mechanism 112 releases the heat generated by an electronic component 2, for example, to the outside of the second chassis 102.

[Electronic Substrate]

As illustrated in FIG. 1, the electronic substrate 10 includes a body 1 (see FIG. 5), an electronic component 2, an adhesive layer 3, and one or more bypass capacitors 4.

The body 1 may be a multilayer substrate (build-up substrate) or a single-layer substrate. In one example, the multilayer substrate is configured by alternately stacking conductive layers and insulating layers. The conductive layers are made of a conductive material containing metal such as copper, silver, or gold. The insulating layers are made of an insulating material, such as epoxy resin, polyimide resin, phenol resin or silicone resin. The insulating layer may be made of a fiber reinforced plastic in which reinforcing fibers are impregnated with resin. In one example, the single-layer substrate is made of the insulating material as described above.

Hereinafter, a part of the mounting surface 11 that overlaps an opposed surface 21 of the electronic component 2 in plan view is called a first area A1. A part of the mounting surface 11 that does not overlap the opposed surface 21 of the electronic component 2 in plan view is called a second area A2. Viewing from a direction perpendicular to the mounting surface 11 is called “plan view”.

On the mounting surface 11, a free area (keep-out area) on which other components are not mounted is kept around the electronic component 2. In one example, the keep-out area is a frame-like area surrounding the electronic component 2. The keep-out area prevents the adhesive from reaching the electronic component mounted on the mounting surface 11 when the adhesive layer 3 is formed. The keep-out area also facilitates the reworking of the electronic component 2.

The electronic component 2 is placed on the mounting surface 11 that is one of the surfaces of the body 1. Examples of the electronic component 2 include a central processing unit (CPU), a graphics processing units (GPU), and a communication module. The CPU is a processor that executes application programs and performs general processing. The GPU is a processor that performs image processing. The CPU is an example of the “processor”. The GPU is another example of the “processor”.

In one example, the electronic component 2 has a rectangular shape (e.g., oblong shape) in plan view. The opposed surface 21 is one of the surfaces of the electronic component 2.

As illustrated in FIG. 3, the electronic component 2 is a plate, and is installed so that the opposed surface 21 faces the mounting surface 11. The electronic component 2 is mounted on the mounting surface 11 by a joint 13 made of solder or the like.

As illustrated in FIG. 1, the opposed surface 21 is rectangular (e.g., oblong). Hereinafter, the positional relationship of the components may be described using the XYZ Cartesian coordinate system. X direction is the transverse (short-side) direction of the opposed surface 21. In FIG. 1, X direction is the horizontal direction. +X direction is to the right. −X direction is to the left. Y direction is the longitudinal (long-side) direction of the opposed surface 21. Y direction is orthogonal to X direction in the plane including the opposed surface 21. In FIG. 1, Y direction is the vertical direction. +Y direction is upward. −Y direction is downward. Z direction is orthogonal to X direction and Y direction. In FIG. 1, +Z direction is toward the viewer from the sheet. +Z direction is the height direction.

The outer edges corresponding to four sides of the opposed surface 21 are called a first outer edge 21e, a second outer edge 21f, a third outer edge 21g, and a fourth outer edge 21h. The first to fourth outer edges 21e to 21h extend linearly. The first outer edge 21e and the third outer edge 21g are in Y direction. The second outer edge 21f and the fourth outer edge 21h are in X direction.

The corners corresponding to four corners of the opposed surface 21 are called a first corner 21a, a second corner 21b, a third corner 21c, and a fourth corner 21d. The first corner 21a is defined by the intersection of the fourth outer edge 21h and the first outer edge 21e. The second corner 21b is defined by the intersection of the first outer edge 21e and the second outer edge 21f. The third corner 21c is defined by the intersection of the second outer edge 21f and the third outer edge 21g. The fourth corner 21d is defined by the intersection of the third outer edge 21g and the fourth outer edge 21h.

The bypass capacitor 4 is mounted on the mounting surface 11. The bypass capacitor 4 is placed at a position where at least a part thereof faces the outer edge of the electronic component 2 in plan view. In this embodiment, five bypass capacitors 4 are mounted on the mounting surface 11. These bypass capacitors 4 are called bypass capacitors 4A to 4E. The bypass capacitors 4A and 4B are placed at positions that face the first outer edge 21e in plan view. A part of the bypass capacitor 4C is placed at the position that faces the second outer edge 21f in plan view. The bypass capacitor 4D is placed at the position that faces the second outer edge 21f in plan view. A part of the bypass capacitor 4E is placed at the position that faces the third outer edge 21g in plan view.

In one example, the bypass capacitors 4 have a function of preventing the voltage of the DC power supply from fluctuating when the electronic component 2 operates. The bypass capacitors 4 lower the impedance of the power-supply wiring relative to the grounding wiring, for example. The bypass capacitors 4 filter so that noise components are not transmitted to the circuit, for example.

The body 1 has one or more storage recesses 12 on the mounting surface 11. This embodiment has eight storage recesses 12. The eight storage recesses 12 are called first through fourth corner recesses 12A-12D and first through fourth side recesses 12E-12H.

The first through fourth corner recesses 12A-12D are rectangular (e.g., square) in plan view. The first corner recess 12A is rectangular in plan view, having a first side 12a, a second side 12b, a third side 12c and a fourth side 12d. The first side 12a and the third side 12c face each other. The first side 12a and the third side 12c are in Y direction. The second side 12b and the fourth side 12d face each other. The second side 12b and the fourth side 12d are in X direction. The length of the first side 12a and the third side 12c is smaller than the dimension of the opposed surface 21 in Y direction. The length of the second side 12b and the fourth side 12d is smaller than the dimension of the opposed surface 21 in X direction.

The second through fourth corner recesses 12B-12D are rectangular (e.g., square) in plan view. The second to fourth corner recesses 12B to 12D may have the same shape as the first corner recess 12A.

The first corner recess 12A involves the first corner 21a in plan view. One of the four corners of the first corner recess 12A (corner 12Ac) is located in the first area A1 (the area of the mounting surface 11 that overlaps the opposed surface 21 in plan view). The other three of the four corners are located in the second area A2 (the area of the mounting surface 11 that does not overlap the opposed surface 21 in plan view). Therefore, a part of the first corner recess 12A is located in the first area A1, and the other part of the first corner recess 12A is located in the second area A2. This means that the first corner recess 12A is located from the first area A1 to the second area A2.

The second corner recess 12B involves the second corner 21b in plan view. One of the four corners of the second corner recess 12B (corner 12Bd) is located in the first area A1. The other three of the four corners are located in the second area A2. Therefore, a part of the second corner recess 12B is located in the first area A1, and the other part of the second corner recess 12B is located in the second area A2. This means that the second corner recess 12B is located from the first area A1 to the second area A2.

The third corner recess 12C involves the third corner 21c in plan view. One of the four corners of the third corner recess 12C (corner 12Ca) is located in the first area A1. The other three of the four corners are located in the second area A2. Therefore, a part of the third corner recess 12C is located in the first area A1, and the other part of the third corner recess 12C is located in the second area A2. This means that the third corner recess 12C is located from the first area A1 to the second area A2.

The fourth corner recess 12D involves the fourth corner 21d in plan view. One of the four corners of the fourth corner recess 12D (corner 12Db) is located in the first area A1. The other three of the four corners are located in the second area A2. Therefore, a part of the fourth corner recess 12D is located in the first area A1, and the other part of the fourth corner recess 12D is located in the second area A2. This means that the fourth corner recess 12D is located from the first area A1 to the second area A2.

The first through fourth side recesses 12E-12H are rectangular in plan view. The first side recess 12E is rectangular in plan view, having a first side 12e, a second side 12f, a third side 12g and a fourth side 12h. The first side 12e and the third side 12g face each other. The first side 12e and the third side 12g are in Y direction. The second side 12f and the fourth side 12h face each other. The second side 12f and the fourth side 12h are in X direction. The length of the first side 12e and the third side 12g is smaller than the dimension of the opposed surface 21 in Y direction. The length of the second side 12f and the fourth side 12h is smaller than the dimension of the opposed surface 21 in X direction. In one example, the first side recess 12E has a rectangular shape whose long sides are in Y direction in plan view.

In one example, the third side recess 12G has a rectangular shape whose long sides are in Y direction in plan view. The third side recess 12G may have the same shape as the first side recess 12E.

In one example, the second side recess 12F and the fourth side recess 12H have a rectangular shape whose long sides are in X direction in a plan view. The second side recess 12F and the fourth side recess 12H may be rectangular in shape, which is the same in shape as the first side recess 12E except that the long sides are in X direction.

The first side recess 12E (see FIGS. 1 and 2) involves a part of the first outer edge 21e (for example, a part including the center in the length direction of the first outer edge 21e) in plan view. Two of the four corners of the first side recess 12E (corners 12Ec and 12Ed) are located in the first area A1. The other two of the four corners are located in the second area A2. Therefore, a part of the first side recess 12E is located in the first area A1, and the other part of the first side recess 12E is located in the second area A2. This means that the first side recess 12E is located from the first area A1 to the second area A2.

The second side recess 12F involves a part of the second outer edge 21f (for example, a part including the center in the length direction of the second outer edge 21f) in plan view. Two of the four corners of the second side recess 12F (corners 12Fa and 12Fd) are located in the first area A1. The other two of the four corners are located in the second area A2. Therefore, a part of the second side recess 12F is located in the first area A1, and the other part of the second side recess 12F is located in the second area A2. This means that the second side recess 12F is located from the first area A1 to the second area A2.

The third side recess 12G (see FIGS. 1 and 2) involves a part of the third outer edge 21g (for example, a part including the center in the length direction of the third outer edge 21g) in plan view. Two of the four corners of the third side recess 12G (corners 12Ga and 12Gb) are located in the first area A1. The other two of the four corners are located in the second area A2. Therefore, a part of the third side recess 12G is located in the first area A1, and the other part of the third side recess 12G is located in the second area A2. This means that the third side recess 12G is located from the first area A1 to the second area A2.

The fourth side recess 12H involves a part of the fourth outer edge 21h (for example, a part including the center in the length direction of the fourth outer edge 21h) in plan view. Two of the four corners of the fourth side recess 12H (corners 12Hb and 12Hc) are located in the first area A1. The other two of the four corners are located in the second area A2. Therefore, a part of the fourth side recess 12H is located in the first area A1, and the other part of the fourth side recess 12H is located in the second area A2. This means that the fourth side recess 12H is located from the first area A1 to the second area A2.

In the present embodiment, the dimension L1 in which the first corner recess 12A and the second corner recess 12B project outward (+X direction) from the first outer edge 21e is larger than the dimension L2 in which the first side recess 12E protrudes outward (+X direction) from the first outer edge 21e. The dimension L3 in which the second corner recess 12B and the third corner recess 12C project outward (−Y direction) from the second outer edge 21f is larger than the dimension L4 in which the second side recess 12F protrudes outward (−Y direction) from the second outer edge 21f. The dimension L5 in which the third corner recess 12C and the fourth corner recess 12D project outward (−X direction) from the third outer edge 21g is larger than the dimension L6 in which the third side recess 12G protrudes outward (−X direction) from the third outer edge 21g. The dimension L7 in which the fourth corner recess 12D and the first corner recess 12A project outward (+Y direction) from the fourth outer edge 21h is larger than the dimension L8 in which the fourth side recess 12H protrudes outward (+Y direction) from the fourth outer edge 21h.

The first corner recess 12A, the first side recess 12E, and the second corner recess 12B are located side by side at intervals in Y direction. The second corner recess 12B, the second side recess 12F, and the third corner recess 12C are located side by side at intervals in X direction. The third corner recess 12C, the third side recess 12G, and the fourth corner recess 12D are located side by side at intervals in Y direction. The fourth corner recess 12D, the fourth side recess 12H, and the first corner recess 12A are located side by side at intervals in X direction.

As illustrated in FIGS. 3 and 4, in one example, the storage recess 12 has a rectangular cross section orthogonal to the mounting surface 11. The storage recess 12 has a side face 12j perpendicular to the bottom face 12i. The cross-sectional shape of the storage recess 12 is not particularly limited. Examples of the cross-sectional shape of the storage recess 12 include a semicircle, an arc, a V-shape, and a trapezoid.

The storage recess 12 can be formed by laser machining. The stowage recess 12 can be formed by other methods such as cutting.

As illustrated in FIG. 3, the adhesive layer 3 bonds the electronic component 2 to the mounting surface 11. In one example, the adhesive layer 3 is made of a liquid curable resin such as an epoxy resin or a urethane resin. The adhesive layer 3 fills the entire storage recess 12. The adhesive layer 3 is in contact with the bottom face 12i and the side face 12j of the storage recess 12. A part of the adhesive layer 3 bulges from the mounting surface 11. That is, a part of the surface of the adhesive layer 3 reaches a position higher than the mounting surface 11. This means that a part of the adhesive layer 3 is stored in the storage recess 12.

The adhesive layer 3 is in contact with a part of the opposed surface 21 and the outer side face 22 of the electronic component 2. The adhesive layer 3 can be formed by supplying an uncured adhesive into the storage recess 12 and then curing the adhesive by heating or the like.

In this embodiment, a part of the adhesive layer 3 is stored in the storage recess 12. In another embodiment, the entire adhesive layer 3 may be stored in the storage recess 12. That is, the storage recess 12 stores at least a part of the adhesive layer 3.

As illustrated in FIGS. 2 and 3, the adhesive layer 3 is formed over the entire area of the storage recess 12 in plan view. Therefore, a part of the adhesive layer 3 is located in the first area A1, and the other part of the adhesive layer 3 is located in the second area A2. This means that the adhesive layer 3 is located from the first area A1 to the second area A2.

[Advantageous Effects of the Electronic Substrate of this Embodiment]

The electronic substrate 10 is configured to include the storage recess 12 on the mounting surface 11 of the body 1, the storage recess 12 being capable of storing at least a part of the adhesive layer 3. This configuration suppresses the flow of the adhesive to the outside of the electronic component 2 when the adhesive layer 3 is formed. This therefore suppresses the outward protrusion of the adhesive layer 3 from the electronic component 2 (see FIG. 3). As a result, the present embodiment has a small free area (i.e., keep-out area) kept around the electronic component 2. The electronic substrate 10 therefore can be made compact. Such a compact electronic substrate 10 makes it possible to reduce the size and weight of the electronic apparatus 100 (see FIGS. 5 and 6). The compact electronic substrate 10 makes it easier to install high-performance audio equipment and higher capacity of the battery 111, add antennas, and install a heat dissipation mechanism 112 with high heat dissipation performance in the second chassis 102 (see FIGS. 5 and 6).

In this way, the electronic substrate 10 suppresses the outward protrusion of the adhesive layer 3 from the electronic component 2, and this prevents the adhesive layer 3 from extending to other electronic components. Therefore, this is favorable in terms of reworkability of the electronic component 2. For example, in FIG. 1, the first side recess 12E prevents the adhesive layer 3 from reaching the bypass capacitor 4A. Therefore, the electronic component 2 can be removed without damaging the bypass capacitor 4A.

The electronic substrate 10 is configured to bond the electronic component 2 to the body 1 with the adhesive layer 3 in the storage recess 12. This reduces the contact area of the adhesive layer 3 to the electronic component 2 as compared with underfilling that bonds the electronic component 2 to the body 1. This makes it easier to remove the electronic components 2 than the underfilling, and is superior in terms of reworkability.

In the electronic substrate 10, the storage recess 12 is located from the first area A1 to the second area A2 of the mounting surface 11 (see FIG. 3). A part of the storage recess 12 located in the first area A1 increases the contact area of the adhesive layer 3 to the opposed surface 21 and the body 1 in the first area A1, and firmly bonds the electronic component 2 and the body 1.

The second area A2, which is outside of the electronic component 2, has few restrictions on the flow of the adhesive when forming the adhesive layer 3. Such a configuration of a part of the storage recess 12 located in the second area A2 therefore suppresses the outward protrusion of the adhesive layer 3 from the electronic component 2 even when the amount of adhesive is large.

The electronic substrate 10 has a small keep-out area of the electronic component 2, meaning a small distance between the electronic component 2 and the bypass capacitors (see FIG. 1). This improves the power integrity (PI).

The storage recess 12 (corner recesses 12A to 12D) involves the corners 21a to 21d, and this enables a small keep-out area around the corners 21a to 21d that require the strength. This therefore reduces the keep-out area greatly, and makes the electronic substrate 10 compact.

The electronic substrate 10 has the storage recess 12 on the mounting surface 11. This means that the adhesive layer 3 is in contact with the inner face of the storage recess 12 (bottom face 12i and side face 12j). This increases the contact area of the adhesive layer 3 to the body 1, and firmly bonds the electronic component 2 and the body 1. Such an increased bonding strength between the electronic component 2 and the body 1 allows sufficient bonding of the electronic component 2 and the body 1 with a small amount of adhesive. Therefore, the amount of adhesive used can be reduced.

In the electronic substrate 10, the contact area of the adhesive layer 3 to the body 1 increases or decreases with the width and depth of the storage recess 12. Therefore, the bonding strength between the electronic component 2 and the body 1 is adjustable with the width and depth of the storage recess 12.

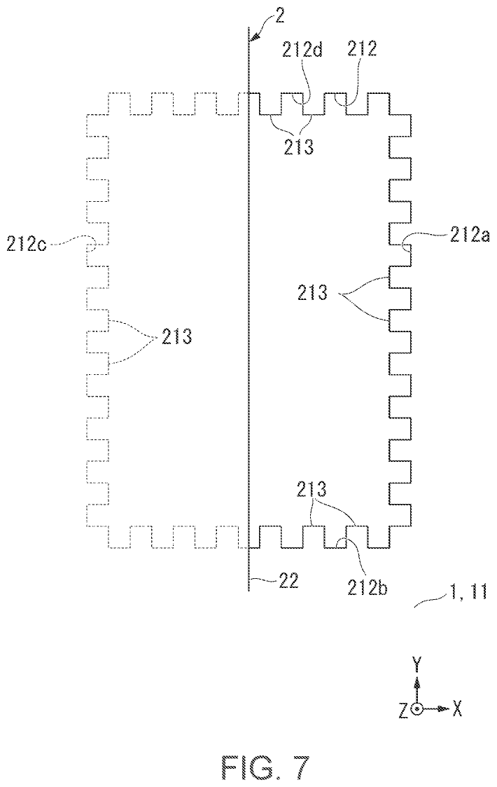

FIG. 7 is a plan view of a storage recess 212 that is a modification example of the storage recess 12.

As illustrated in FIG. 7, the storage recess 212 is substantially rectangular in plan view. The inner edges corresponding to four sides of the storage recess 212 are called a first inner edge 212a, a second inner edge 212b, a third inner edge 212c, and a fourth inner edge 212d.

The first inner edge 212a and the third inner edge 212c have a plurality of protrusions 213 on their inner side faces at intervals in Y direction. The protrusions 213 on the first inner edge 212a protrude in a direction toward the third inner edge 212c. The protrusions 213 on the third inner edge 212c protrude in a direction toward the first inner edge 212a.

The second inner edge 212b and the fourth inner edge 212d have a plurality of protrusions 213 on their inner side faces at intervals in X direction. The protrusions 213 on the second inner edge 212b protrude in a direction toward the fourth inner edge 212d. The protrusions 213 on the fourth inner edge 212d protrude in a direction toward the second inner edge 212b.

In one example, these protrusions 213 are rectangular in plan view.

The neighboring protrusions 213 define a recess therebetween. This can be said that multiple recesses are formed at intervals on the inner side face of the storage recess 212. This also can be said that protrusions and recesses are alternately formed on the inner side face of the storage recess 212. Therefore, it can be said that the inner side face of the storage recess 212 has recesses and protrusions (at least one of recesses and protrusions).

The electronic substrate with the storage recess 212 instead of the storage recess 12 (see FIG. 2) has recesses and protrusions on the inner side face of the storage recess 212. This increases the contact area of the adhesive layer 3 to the body 1, and firmly bonds the electronic component and the body 1. This configuration enhances the reliability of the electronic substrate 10. In addition, such an increased bonding strength between the electronic component 2 and the body 1 is advantageous in narrowing the keep-out area.

The specific configuration of the present invention is not limited to the above-described embodiments, and also includes designs or the like within the scope of the present invention. The configurations described in the above embodiments can be combined freely.

In the electronic substrate 10 of FIG. 1, the storage recess 12 includes the first to fourth corner recesses 12A to 12D and the first to fourth side recesses 12E to 12H. In another embodiment, the storage recess may include only the first to fourth corner recesses or only the first to fourth side recesses.

In the electronic substrate 10, the storage recess 12 includes the first to fourth corner recesses 12A to 12D involving the four corners (first to fourth corners 21a to 21d) of the opposed surface 21, and the storage recess does not always have to involve all of the four corners of the opposed surface of the electronic component. For example, the storage recess may involve at least one of the four corners of the opposed surface of the electronic component.

In the electronic substrate 10, the storage recess 12 includes the first to fourth side recesses 12E to 12H involving the center portions of the four sides of the opposed surface 21, and all of the four sides of the opposed surface of the electronic component do not always have to have the storage recess. For example, the storage recess may involve a part of at least one of the four sides of the opposed surface of the electronic component.

Although FIG. 3 illustrates the electronic substrate 10 including the storage recess 12 located from the first area A1 to the second area A2, the storage recess may be located only in the first area or only in the second area.

1. An electronic substrate comprising:
a body having a mounting surface;
an electronic component having an opposed surface facing the mounting surface; and
an adhesive layer that bonds the electronic component to the mounting surface,
the mounting surface having a storage recess in which at least a part of the adhesive layer is disposed.

2. The electronic substrate according to claim 1, wherein the electronic substrate has a first area that overlaps the opposed surface and a second area that does not overlap the opposed surface, and the storage recess is disposed from the first area to the second area.

3. The electronic substrate according to claim 1, wherein the electronic component is rectangular, and
the storage recess is disposed at least at one corner of the electronic component.

4. The electronic substrate according to claim 1, wherein the storage recess has an inner side face having recesses and protrusions thereon.

5. The electronic substrate according to claim 1, wherein the electronic component includes a processor, and
the electronic substrate includes at least one bypass capacitor on the mounting surface and at a position opposing an outer edge of the electronic component.

6. An electronic apparatus comprising the electronic substrate according to claim 1.
